(19) United States
(12) Patent Application Publication
(10) Pub. No.: US 2013/0100613 A1
(43) Pub. Date: Apr. 25, 2013

(54) FAN UNIT, ELECTRONIC DEVICE, AND METHOD FOR MANUFACTURING FAN UNIT

(71) Applicant: Masatoshi Nakai, Tokyo (JP)

(72) Inventor: Masatoshi Nakai, Tokyo (JP)

(73) Assignee: NEC CORPORATION, Tokyo (JP)

(21) Appl. No.: 13/807,248

(22) PCT Filed: Jun. 22, 2011
(86) PCT No.: PCT/JP2011/064287

§ 371 Date: Dec. 27, 2012

(30) Foreign Application Priority Data
Jun. 28, 2010 (JP) 2010-146169

(51) Int. Cl. H05K 7/20

(52) U.S. Cl. CPC H05K 7/20136; H05K 7/20172
USPC 361/695; 415/213.1; 29/592.1

(57) ABSTRACT

Provided is a fan unit that includes: a plurality of fans (3) arrayed in a direction intersecting an air blowing direction; printed circuit board (4) to which the plurality of fans (3) are electrically connected; chassis (5) having back portion (5a) with which surfaces (3a) of the plurality of fans (3) orthogonal to the air blowing direction are engaged and bottom portion (5b) supporting the plurality of fans (3), in which printed circuit board (4) is disposed; and bracket (6) having fixing portion (6c) fixed to bottom portion (5b) of chassis (5) by screws and configured to sandwich the plurality of fans (3) engaged with back portion (5a) of chassis (5) in cooperation with back portion (5a).

### TECHNICAL FIELD

The present invention relates to a fan unit for cooling the inside of an electronic device, the electronic device including the fan unit, and a method for manufacturing the fan unit.

### BACKGROUND ART

In an electronic device such as an information processing device, a fan is used as an axial blower for cooling a heat generation component included in a control circuit or the like mounted therein. As an electronic device of this type, there is known a device including a fan unit in which a plurality of independent fans are arrayed in a direction orthogonal to an air blowing direction (e.g. refer to Patent Literature 1).

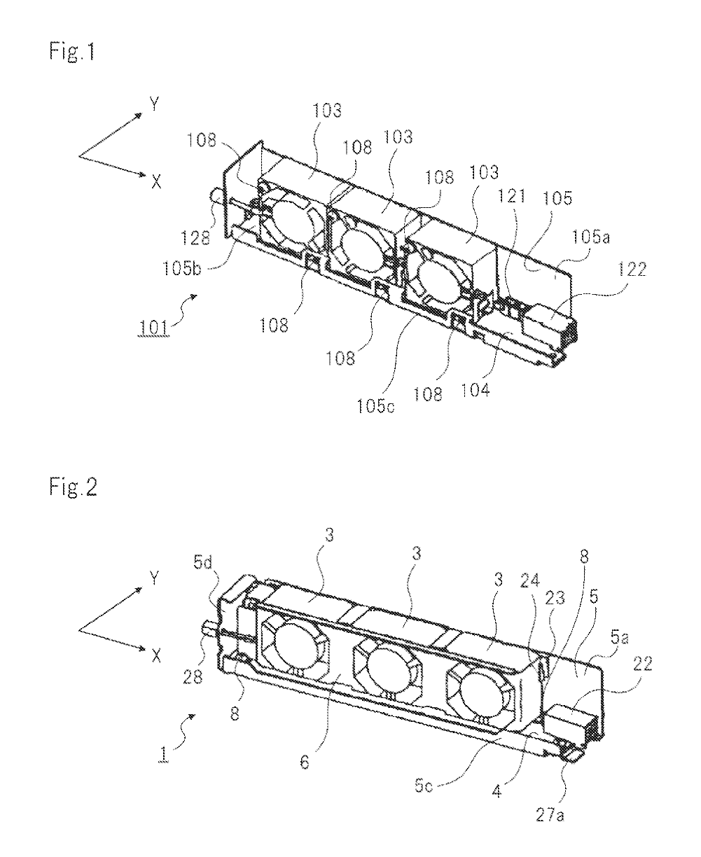

FIG. 1 is a perspective view showing an example of a fan unit related to the present invention. As shown in FIG. 1, fan unit 101 related to the present invention includes a plurality of fans 103, chassis 105 for supporting the plurality of fans 103, and printed circuit board 104 electrically connected to the plurality of fans 103.

Each fan 103 includes a fan cable (not shown) electrically connected to printed circuit board 104. Chassis 105 includes back portion 105a to which each fan 103 is fixed by screws, bottom portion 105b orthogonal to back portion 105a, and front portion 105c facing back portion 105a. In bottom portion 105b of chassis 105, the plurality of fans 103 are arrayed in an X axis direction orthogonal to the air blowing direction shown in FIG. 1. In back portion 105a of chassis 105, a plurality of suction ports (not shown) corresponding to fans 103 are formed, and each fan 103 is set in a position corresponding to each suction port. Each fan 103 is fixed to back portion 105a of chassis 105 by inserting two fixing screws 108 into holes (not shown) bored at two corners from a Y axis direction shown in FIG. 1.

Printed circuit board 104 includes a plurality of connectors 121 electrically connected to the plurality of fans 103 via the fan cables, and power connector 122 electrically connected to connectors 121. Printed circuit board 104 is fixed to one end of bottom portion 105b of chassis 105 by two fixing screws (not shown). The fan cable of each fan 103 is drawn along the inside of front portion 105c of chassis 105 to printed circuit board 104, and electrically connected to each connector 121.

Fan unit 101 thus configured is fixed to a mounting portion disposed in the back portion of the electronic device, and electrically connected to power connector 122 of printed circuit board 104 by inserting the connection plug (not shown) of the electronic device side. In fan unit 101 fixed to the mounting portion of the electronic device, chassis 105 is fixed to the mounting portion by chassis fixing screw 128.

### CITATION LIST

Patent Literature 1: JP5-25794A

### SUMMARY OF INVENTION

### Problems to be Solved by Invention

In the aforementioned configuration related to the present invention, the two fixing screws are used for fixing one fan to the chassis. Thus, in the manufacturing process of the fan unit, for fan assembling work, work time calculated by [time for screwing two fixing screws]×[number of fans] is necessary, and the assembling work of the plurality of fans is cumbersome.

In the configuration related to the present invention, to electrically connect each fan to the printed circuit board disposed at one end of the bottom portion of the chassis, the fan cable extended from each fan must be drawn along the inside of the front portion of the chassis to be electrically connected to the connector of the printed circuit board. Consequently, wiring work is cumbersome.

In the configuration related to the present invention, as a structure for preventing removal of the fan cable drawn along the front portion of the chassis from the chassis, for example, engaging pieces must be formed by bending parts of the chassis in a plurality of places of the front portion of a chassis member, and work for hooking the fan cable to each engaging piece must be carried out. Further, since, in particular, an extra length is added to the fan cable of the fan adjacent to the printed circuit board in order to allow for slack in the electrically connected state to the connector, for example, in the back portion of the chassis, cable processing for fixing and holding the extra length part of the fan cable by a banding band must be carried out.

Further, in the configuration related to the present invention, to surely fix the fan to the back portion of the chassis, the leading end of the fixing screw is projected from the back portion of the chassis to the outside of the back portion in the plate thickness direction of the back portion. Consequently, a space including the part of the fixing screw that is projected from the back portion is not used effectively and is thus wasted. Since the leading end of the fixing screw is projected from the back portion of the chassis, a space must be secured for preventing interference with the leading end of the fixing screw on the chassis side of the fan or the electronic device side on which the fan unit is mounted.

Thus, for example, if the size between the front portion and the back portion of the electronic device is restricted by the specifications of the electronic device, when the fan unit is disposed in the back portion of the electronic device, no sufficient space can be secured to dispose a display element such as a light-emitting diode in the front portion of the electronic device side, thus limiting the choice that a designer has in designing the electronic device.

It is therefore an object of the present invention to provide a fan unit capable of solving any one of the problems of the related art, an electronic device, and a method for manufacturing the fan unit. An exemplary object of the present invention is to simplify the work of assembling a plurality of fans side by side in a chassis member.

### Solution to Problem

To achieve the object, a fan unit according to the present invention includes: a plurality of fans arrayed in a direction intersecting an air blowing direction; a wiring board to which the plurality of fans is electrically connected; a chassis member having a side wall portion with which the surfaces of the plurality of fans orthogonal to the air blowing direction are engaged and a bottom portion supporting the plurality of fans, in which the wiring board is disposed; and a bracket member having a fixing portion fixed to the bottom portion of the chassis member by screws and configured to sandwich the plurality of fans engaged with the side wall portion of the chassis member in cooperation with the side wall portion.

A method for manufacturing a fan unit according to the present invention includes: the fan engaging step of engaging the surfaces of a plurality of fans arrayed in a direction intersecting an air blowing direction and orthogonal to the air blowing direction with the side wall portion of a chassis member; the board disposing step of disposing a wiring board to which the plurality of fans are electrically connected in the bottom portion of the chassis member supporting the plurality of fans; and the bracket fixing step of sandwiching the plurality of fans engaged with the side wall portion of the chassis member between the side wall portion and a bracket member, and fixing the fixing portion of the bracket member to the bottom portion of the chassis member by screws.

### Effects of Invention

According to the present invention, the work of assembling the plurality of fans to the chassis member can be simplified, and the assembling work time of the plurality of fans can be shortened.

Furthermore, according to the present invention, to assemble the plurality of fans to the chassis member, the fixing portion of the bracket member is fixed to the bottom portion of the chassis member by the screws. Thus, if no part of the fixing screws projects from the side wall portion of the chassis member to the outside of the side wall portion, a space including parts of the fixing screws projected from the side wall portion can be effectively used.

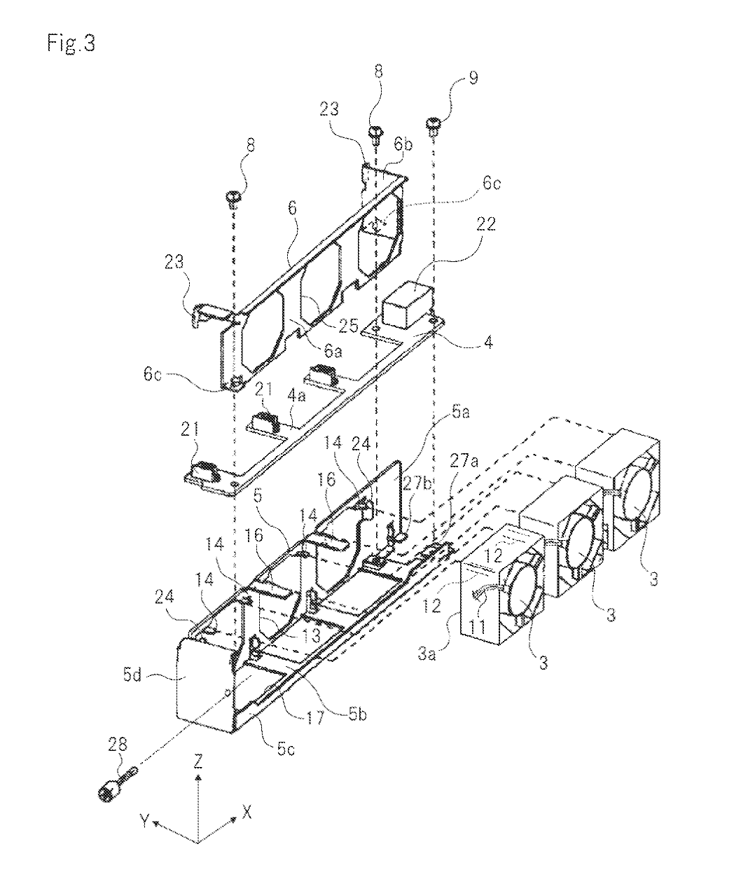

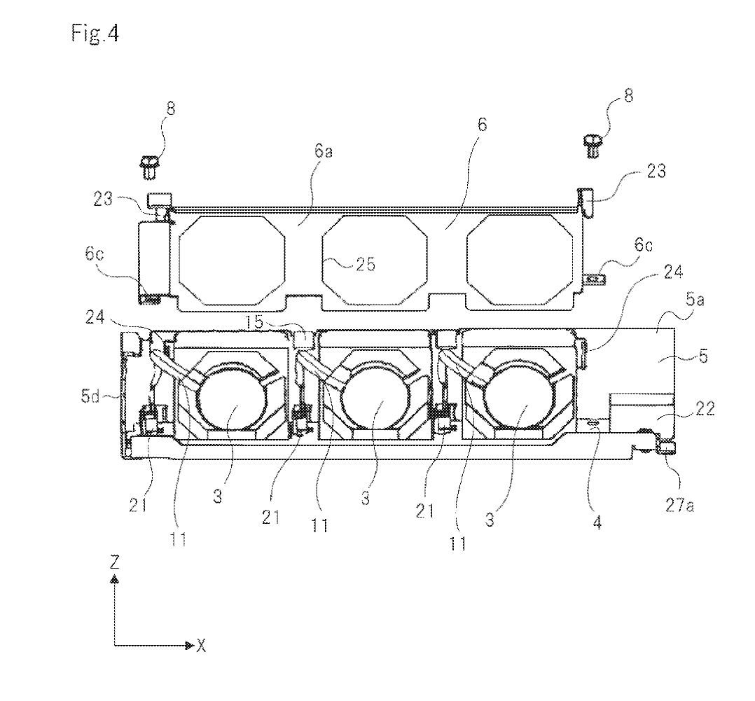

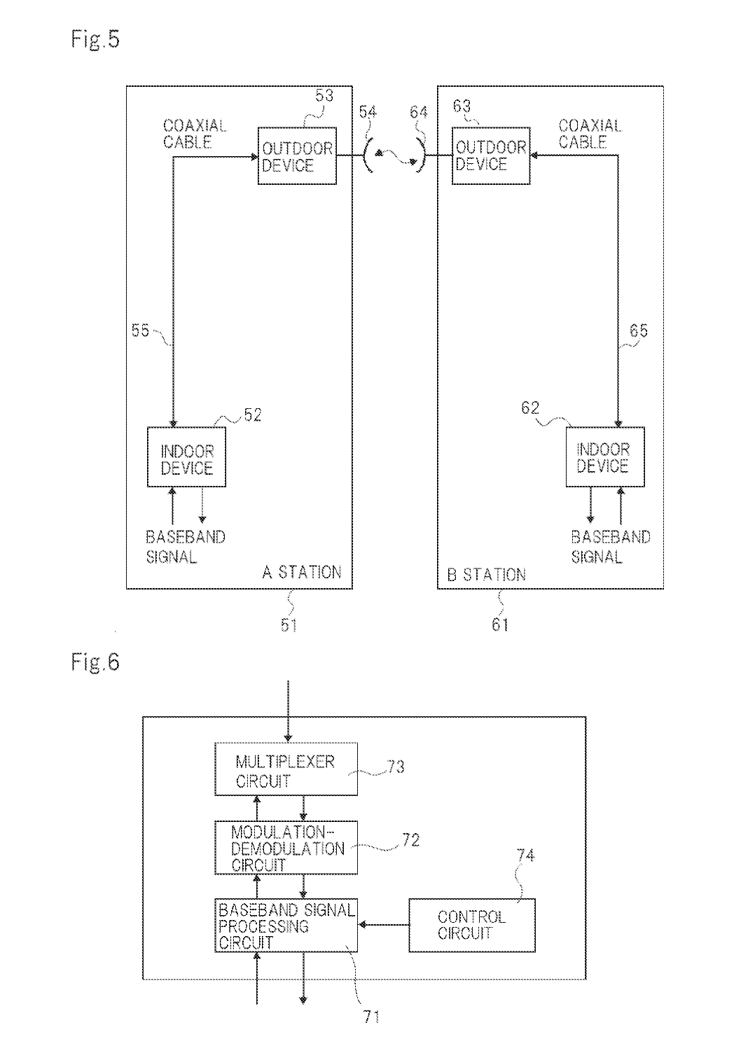

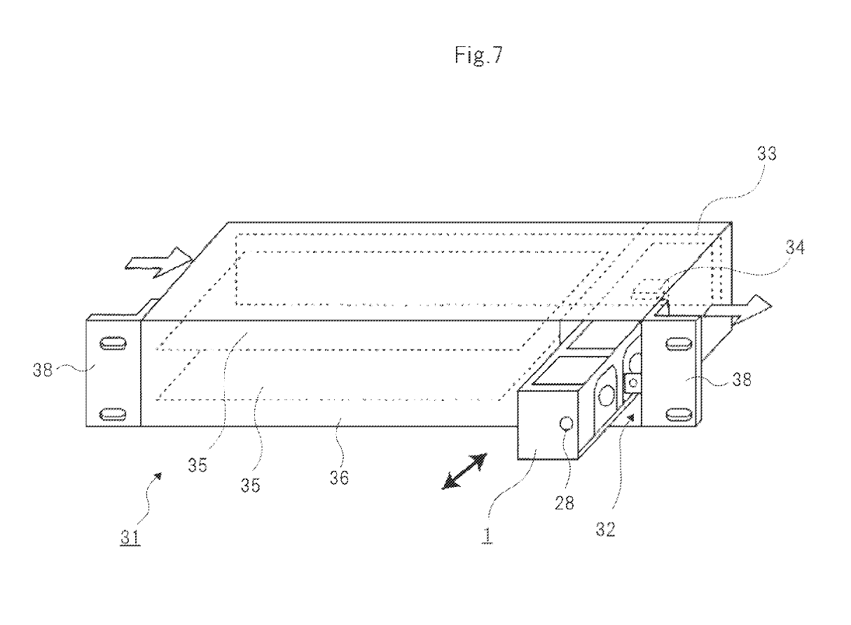

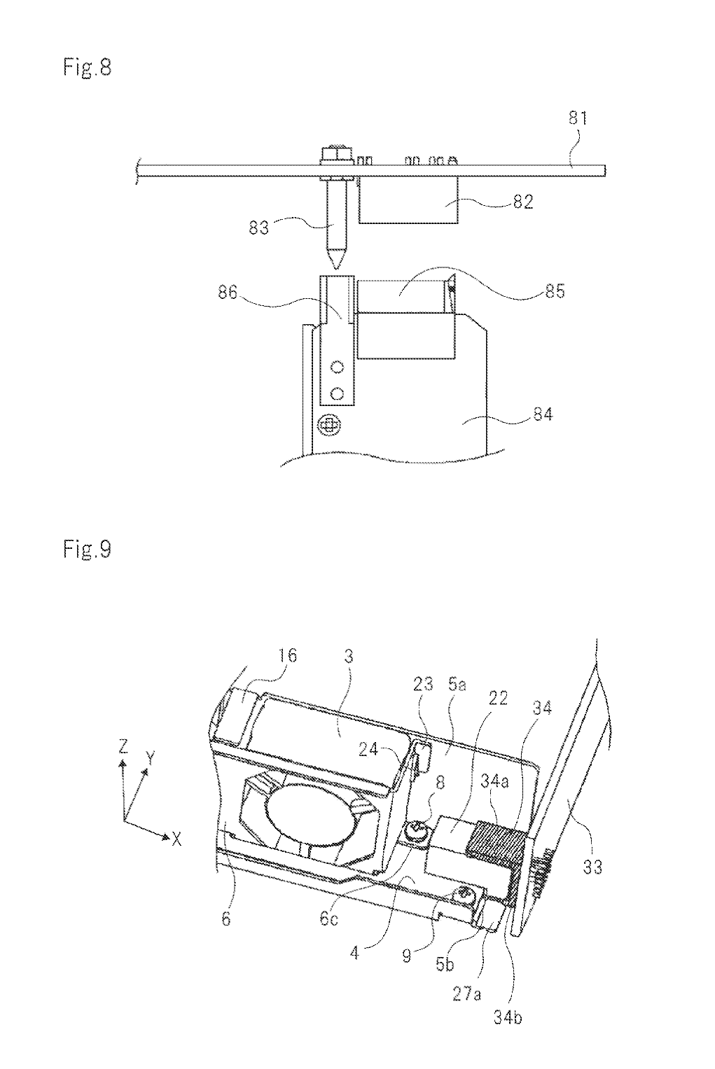

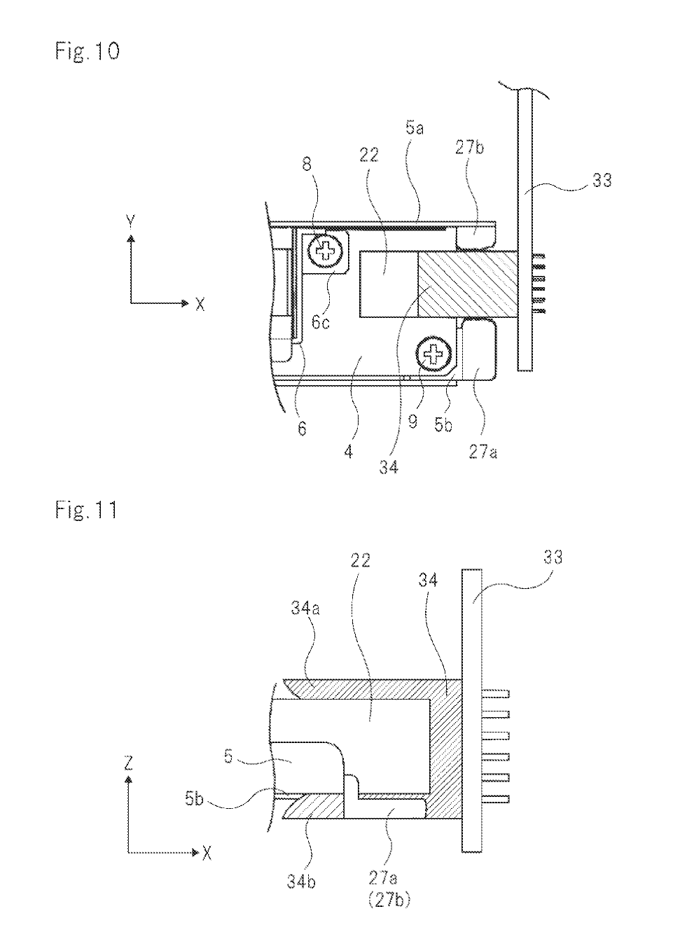

### BRIEF DESCRIPTION OF DRAWINGS

[FIG. 1] A perspective view showing a fan unit related to the present invention.

[FIG. 2] A perspective view showing a fan unit according to an embodiment.

[FIG. 3] An exploded perspective view showing the fan unit according to the embodiment.

[FIG. 4] An exploded perspective view showing the ongoing assembling state of the fan unit according to the embodiment.

[FIG. 5] A block diagram showing an example of a wireless communication device using the fan unit according to the embodiment.

[FIG. 6] A block diagram showing an example of an indoor device included in the wireless communication device using the fan unit according to the embodiment.

[FIG. 7] A perspective view schematically showing the indoor device to which the fan unit, according to the embodiment, is fixed.

[FIG. 8] A plan view showing the configuration example of a guide structure for guiding the power connector of the fan unit side to the connection plug of the electronic device side.

[FIG. 9] An exploded perspective view showing the guide structure of the fan unit according to the embodiment.

[FIG. 10] A plan view showing the guide structure of the fan unit according to the embodiment.

[FIG. 11] A side view showing the guide structure of the fan unit according to the embodiment.

### DESCRIPTION OF EMBODIMENTS

Hereinafter, the specific embodiment of the present invention will be described with reference to the drawings.

FIG. 2 is a perspective view showing a fan unit according to an embodiment. FIG. 3 is an exploded perspective view showing the fan unit according to the embodiment. FIG. 4 is an exploded perspective view showing the ongoing assembling state of the fan unit according to the embodiment.

As shown in FIGS. 2 and 3, fan unit 1 according to the embodiment includes a plurality of fans 3 arrayed in an X axis direction orthogonal to the air blowing direction shown in FIG. 1, printed circuit board 4 as a wiring board to which the plurality of fans 3 are electrically connected, and chassis 5 as a chassis member for supporting the plurality of fans 3. Chassis 5 includes back portion 5a as a side wall portion with which surfaces 3a of the plurality of fans 3 orthogonal to the air blowing direction are engaged, and bottom portion 5b as a bottom portion for supporting the plurality of fans 3, in which printed circuit board 4 is disposed.

As shown in FIGS. 3 and 4, fan unit 1 further includes bracket 6 as a bracket member having fixing portion 6c fixed to bottom portion 5b of chassis 5 by screws and configured to sandwich the plurality of fans 3 engaged with back portion 5a of chassis 5 between back portion 5a and front portion 6a described below, and two fixing screws 8 for screwing fixing portion 6c of bracket 6 to bottom portion 5b of chassis 5.

As shown in FIG. 3, fan 3, which is an axial blower, includes fan cable 11 electrically connected to printed circuit board 4. Fan 3 further includes insertion holes 12 formed in the two places of surface 3a of a suction side to be engaged with chassis 5.

As shown in FIG. 3, chassis 5 includes, on back portion 5a, a plurality of suction ports 13 formed corresponding to fans 3. In back portion 5a, insertion pieces 14 are formed around suction ports 13 to be engaged with insertion holes 12 of fans 3. Chassis 5 further includes, in back portion 5a, regulation piece 16 formed to prevent connector cable 11, located between the plurality of fans 3 and electrically connected to printed circuit board 4 to the outside of chassis 5, from jumping out.

In bottom portion 5b of chassis 5, openings 17 are formed so that the bottom sides of fans 3 can fit therein. Chassis 5 includes front portion 5c facing back portion 5a, and side portion 5d orthogonal to back portion 5a and bottom portion 5b. When bracket 6 is mounted to chassis 5, the lower end of bracket 6 abuts on the inside of front portion 5c of chassis 5.

In printed circuit board 4, a portion corresponding to the bottom surface of each fan 3 is notched and, between fans 3 adjacent to each other, a plurality of connectors 21 are disposed to be electrically connected to the plurality of fans 3 via fan cables 11. Printed circuit board 4 includes wiring portion 4a disposed between fans 3, and connector 21 is disposed in wiring portion 4a. At the end of printed circuit board 4, power connector 22 electrically connected to each connector 21 via wiring portion 4a is disposed.

Printed circuit board 4 is located at one end of bottom portion 5b of chassis 5, and fixed by two fixing screws 8 and one fixing screw 9. Specifically, printed circuit board 4 is sandwiched between fixing portion 6c of bracket 6 and bottom portion 5b of chassis 5 to be fixed by fixing screws 8, and fixed on bottom portion 5b of chassis 5 by fixing screw 9.

As shown in FIG. 3, bracket 6 includes front portion 6a for covering the air blowing side of each fan 3, and side portion 6b for covering one end side of the plurality of arrayed fans 3. When bracket 6 is mounted to chassis 5, the plurality of fans 3 supported on bottom portion 5b of chassis 5 is surrounded with back portion 5a, front portion 5c, and side portion 5d of chassis 5 and front portion 6a and side portion 6b of bracket 6, and the plurality of arrayed fans 3 are firmly held.

A plurality of air blowing ports 25 are formed in front portion 6a of bracket 6 corresponding to fans 3. In bracket 6, sets of fixing portions 6c screwed to bottom portion 5b of chassis 5 are respectively formed at one end of front portion 6a and one end of side portion 6b.

As shown in FIGS. 3 and 4, bracket 6 further includes a set of engaging pieces 23 as engaging means engaged with back portion 5a of chassis 5. The set of engaging pieces 23 is formed by bending parts of bracket 6. In back portion 5a of chassis 5, a set of cut and raised pieces 24 is bent to be formed as engaging means engaged with engaging pieces 23 of bracket 6.

When fan unit 1 is fixed to the mounting portion of the electronic device, side portion 5d of chassis 5 is fixed to the mounting portion by chassis fixing screw 28.

For fan unit 1 thus configured, the operation of assembling the plurality of fans 3 to chassis 5 will be described.

First, insertion piece 14 disposed in back portion 5a of chassis 5 is inserted into insertion hole 12 of fan 3, and each fan 3 is temporarily fixed to back portion 5a of chassis 5. Then, after fan cable 11 of fan 3 is inserted into connector 21 mounted on printed circuit board 4, as shown in FIG. 4, printed circuit board 4 is placed in a predetermined position on bottom portion 5b of chassis 5.

Then, after printed circuit board 4 has been placed in the predetermined position on chassis 5, bracket 6 is lowered toward bottom portion 5b of chassis 5 from above in a Z axis direction shown in FIG. 4. In this case, the set of engaging pieces 23 of bracket 6 is engaged with the set of cut and raised pieces 24 disposed in the two places of back portion 5a of chassis 5.

Then, after confirmation of the engaged state of bracket 6 with chassis 5, fixing portion 6c of bracket 6 is mounted on printed circuit board 4, and two fixing portions 6c are fixed to bottom portion 5b of chassis 5 by two fixing screws 8 when part of printed circuit board 4 is sandwiched between fixing portion 6c and bottom portion 5b of chassis 5. Accordingly, bracket 6 is fastened to bottom portion 5b of chassis 5 jointly with printed circuit board 4 by fixing screws 8.

Lastly, as shown in FIG. 3, printed circuit board 4 is fixed to bottom portion 5b of chassis 5 by fixing screw 9. When fan unit 1 is fixed to the mounting portion of the electronic device, side portion 5d of chassis 5 is fixed to the mounting portion by chassis fixing screw 28.

As described above, according to fan unit 1 of the embodiment, each fan 3 is inserted into insertion piece 14 of back portion 5a of chassis 5 to be temporarily fixed, and bracket 6 is engaged with chassis 5, and then fixed to bottom portion 5b of chassis 5 jointly with printed circuit board 4 by two fixing portions 6c using two fixing screws 8. Thus, the plurality of fans 3 can be fixed to chassis 5. In other words, in fan unit 1, instead of directly fixing each fan 3 to chassis 5 by fixing screws 8, bracket 6 configured to sandwich fan 3 in cooperation with back portion 5a of chassis 5 is fixed to bottom portion 5b of chassis 5. Thus, since the number of screwing times for assembling the plurality of fans 3 to chassis 5 can be reduced, as the first effect of fan unit 1 according to this embodiment, assembling work time can be shortened. As a result, according to this embodiment, the productivity of fan unit 1 can be improved.

As the second effect of this embodiment, fan 3 is not screwed to back portion 5a of chassis 5. This eliminates the necessity of projecting the fixing screw from the back portion of the chassis to the outside as in the case of the related art, and enables effective use of space including the projected part of the fixing screw. In other words, according to this embodiment, the space damaged by the leading end of the fixing screw projected from the back portion of the chassis in the related art can be used for increasing the width of bottom portion 5b of chassis 5 in a Y axis direction shown in FIG. 3. By increasing the width of bottom portion 5b of chassis 5, the portion for disposing connector 21 and wiring portion 4a for connecting connector 21 to power connector 22 can be secured in the width direction of bottom portion 5a. As a result, printed circuit board 4 can be formed in the entire longitudinal direction of bottom portion 5b of chassis 5 as the X axis direction shown in FIG. 3 so that a plurality of connectors 21 can be disposed among the plurality of fans 3.

Therefore, as the third effect of this embodiment, by including printed circuit board 4 having connector 21 disposed between fans 3 and adjacent to each other to be connected to fan cables 11 of fans 3, a drawing distance of fan cable 11 until it is connected to connector 21 can be shortened. In other words, according to this embodiment, each fan 3 and each connector 21 can be electrically connected to each other by the shortest distance, and it is not necessary to carry out cable processing for the extra length part of fan cable 11. Further, since fan cable 11 is prevented from being projected outside from chassis 5, when fan unit 1 is fixed to the mounting portion of the electronic device, fan cable 1 can be prevented from being accidentally sandwiched between the mounting portion and fan unit 1.

According to this embodiment, even when the number of fans 3 is appropriately changed according to the specifications of the electronic device using fan unit 1, the configuration of this embodiment can be easily used, providing the same effects as those described above. The fan unit according to the present invention is configured such that three fans 3 are fixed to chassis 5. Needless to say, however, the fan unit can be configured such that only one fan 3 is fixed to chassis 5.

An example of the electronic device using the fan unit according to this embodiment is a wireless communication device for interconnecting wireless base stations by wireless communication, which is used in a mobile communication system. Such wireless communication devices are divided into an outdoor device (hereinafter, ODU) and an indoor device (hereinafter, IDU), and a configuration for connecting the ODU and the IDU to each other by a coaxial cable or the like is generally used (refer to JP2006-197343A). The ODU installed outdoors with an antenna has a function of transmitting or receiving a signal. The IDU installed indoors has a function of modulating-demodulating or processing a signal.

FIG. 5 is a block diagram showing an example of the wireless communication device. FIG. 6 is a block diagram showing an example of the IDU included in the wireless communication device.

As shown in FIG. 5, A station 51 (B station 61) includes IDU 52 (62) that inputs or outputs a baseband signal to modulate or demodulate it, ODU 53 (63) that is a wireless transmitter-receiver, coaxial cable 55 (65) that serves as an interface between IDU 52 (62) and ODU 53 (63), and antenna 54 (64) that is connected to ODU 53 (63) to carry out wireless transmission or reception with an opposite station.

As shown in FIG. 6, IDU 52 (62) of A station 51 (B station 61) includes baseband signal processing circuit 71, modulation-demodulation circuit 72, multiplexer circuit 73, and control circuit 74. Baseband signal processing circuit 71 has a function of processing an input baseband signal to output it to modulation-demodulation circuit 72, and a function of outputting the signal demodulated and reproduced by modulation-demodulation circuit 72 as a baseband signal to an external device.

The IDU includes such precision electronic components, and the fan unit according to the present invention is used for cooling the precision electronic components. In this fan unit, detachability is desirable to facilitate changing the number of fans, and miniaturization is also required.

Hereinafter, the mounted state of fan unit 1 thus configured in the IDU of the wireless communication device will be described. FIG. 7 is a perspective view schematically showing the IDU to which fan unit 1 according to the embodiment is fixed.

As shown in FIG. 7, IDU 31 of the wireless communication device includes fan unit 1 of the embodiment, mounting portion 32 to which fan unit 1 is fixed, backside wiring board 33 having connection plug 34 electrically connected to power connector 22 of fan unit 1, a plurality of circuit boards 35 on which various electronic elements as electronic components cooled by fan unit 1 are mounted, and case 36 for covering these portions.

Mounting portion 32, which is disposed from the front portion to the back portion of case 36, is formed into a slot-in structure where fan unit 1 is detachable from the front portion of IDU 31. On the front sides of both side portions of case 36, fixing members 38 are arranged to be screwed to a rack (not shown) when attached to the rack on which a plurality of IDUs 31 are stacked.

In IDU 31 thus configured, the plurality of circuit boards 35 are cooled by fan unit 1 using air sucked from one side portion of case 36. The air that has cooled the plurality of circuit boards 35 is discharged from the other side portion of case 36 by fan unit 1.

Thus, as shown in FIG. 7, fan unit 1 is attached to mounting portion 32 of IDU 31 of the wireless communication device by being inserted into mounting portion 32. Power connector 22 of fan unit 1 is accordingly connected to connection plug 34 of the IDU side. Thus, in the case of fixing fan unit 1 to mounting portion 32, when power connector 22 is positionally shifted from connection plug 34 because of the influence of the size tolerance of the peripheral wall of mounting portion 32, the chassis of fan unit 1 or the like, a connection failure or collision between power connector 22 and connection plug 34 may occur to damage connection plug 34. This necessitates a guide structure for guiding and connecting power connector 22 of fan unit 1 to connection plug 34.

FIG. 8 is a plan view showing a configuration example of such a guide structure. An example of the guide structure may be, as shown in FIG. 8, a configuration where guide pin 83 for guiding power connector 85 is formed in a position adjacent to connection plug 82 mounted on backside wiring board 81, and guide member 86 into which guide pin 83 is inserted is formed in a position adjacent to power connector 85 mounted on printed circuit board 84. In the case of this configuration, however, a space for disposing guide member 86 must be secured in printed circuit board 84. This enlarges printed circuit board 84, consequently enlarging the entire fan unit. It is therefore difficult to employ the guide structure using guide pin 83 for the fan unit desired to be miniaturized. In addition, since guide member 86 or guide pin 83 must be added to the fan unit or the mounting portion, manufacturing costs may be disadvantageously increased.

Thus, in fan unit 1 according to this embodiment, the guide structure for guiding power connector 22 to the connection plug is arranged in a simply configuration. FIG. 9 is a perspective view showing the guide structure of fan unit 1 according to this embodiment. FIG. 10 is a plan view showing the guide structure of fan unit 1 according to this embodiment. FIG. 11 is a side view showing the guide structure of fan unit 1 according to this embodiment.

As shown in FIGS. 9 and 10, at one end of bottom portion 5b of chassis 5 included in fan unit 1 according to this embodiment, a pair of guide pieces 27a and 27b slid into contact along both side surfaces of connection pug 34 to be connected is disposed on both sides of power connector 22 in the Y axis direction. Guide pieces 27a and 27b are formed by bending bottom portion 5b of chassis 5. Guide pieces 27a and 27b are accordingly formed integrally with chassis 5.

Backside wiring board 33 having connection plug 34 is disposed in mounting portion 32 of the IDU to be connected to a power source (not shown). As shown in FIG. 11, connection plug 34 installed on the IDU side is formed into a U-shaped cross-section, and includes a pair of upper piece 34a and lower piece 34b to sandwich the upper surface and the lower surface of power connector 22 installed on the side of fan unit 1.

When power connector 22 is inserted into or pulled out from connection plug 34, the pair of guide pieces 27a and 27b formed at the leading end of chassis 5 sandwiches lower piece 34b of connection plug 34 from both sides, and guides power connector 22 to a correct position of connection pug 34 in the Y axis direction. Further, since they are formed by bending chassis 5, guide pieces 27a and 27b are formed to be extremely compact with a thickness equal to that of chassis 5.

When fan unit 1 thus configured is fixed to mounting portion 32, the pair of guide pieces 27a and 27b arranged on both sides of power connector 22 in a width direction parallel to the width direction of bottom portion 5b of chassis 5 are slid into contact along both side surfaces of lower piece 34b of connection plug 34. Accordingly, connection plug 34 is positioned in the width direction of power connector 22 to be guided toward power connector 22 by the pair of guide pieces 27a and 27b. Power connector 22 and connection plug 34 are accurately positioned to be electrically interconnected. When fan unit 1 is fixed to mounting portion 32, by sandwiching power connector 22 between the pair of upper piece 34a and lower piece 34b from above and below, connection plug 34 is positioned in the Z axis direction shown in FIG. 11 with respect to power connector 22.

As described above, according to fan unit 1 of this embodiment, because of the inclusion of the pair of guide pieces 27a and 27b for guiding power connector 22 to connection plug 34, when fan unit 1 is fixed to mounting portion 32, power connector 22 and connection plug 34 are accurately positioned to be electrically connected to each other. Thus, according to this embodiment, the reliability of the electrically connected state can be improved by preventing damage to power connector 22 or connection plug 34. As a result, according to this embodiment, by the simple structure where it is not necessary to add any other components for the guide structure to fan unit 1 or IDU 31, a configuration where fan unit 1 is easily detachable from mounting portion 32 of IDU 31 can be realized.

The embodiment has been described by way of example where detachable fan unit 1 is applied to indoor device (IDU) 31 of the radio communication device. However, fan unit 1 can be used for other electronic devices such as an information communication device.

The fan unit structure of this embodiment enables simplification of the work for changing the number of fans 3 according to the specifications of each electronic device of this type and the maintenance work for assembling or disassembling the plurality of fans 3.

The embodiments of the present invention have been described. However, the present invention is not limited to the embodiments. Various changes understandable to those skilled in the art can be made to the configuration and the specifics of the present invention without departing from the scope of the invention.

This application claims priority from Japanese Patent Application No. 2010-146169 filed Jun. 28, 2010, which is hereby incorporated by reference herein in its entirety.

### REFERENCE NUMERALS

1 Fan unit

3 Fan

3a Surface

4 Printed circuit board

5 Chassis

5a Back portion

5b Bottom portion

6 Bracket

6c Fixing portion

8 Fixing screw

11 Fan cable

21 Connector

22 Power connector

23 Engaging piece

24 Cut and raised piece

1. A fan unit comprising:
a plurality of fans arrayed in a direction intersecting an air blowing direction;
a wiring board to which the plurality of fans is electrically connected;
a chassis member having a side wall portion with which surfaces of the plurality of fans orthogonal to the air blowing direction are engaged and a bottom portion supporting the plurality of fans, in which the wiring board is disposed; and
a bracket member having a fixing portion fixed to the bottom portion of the chassis member by screws and configured to sandwich the plurality of fans engaged with the side wall portion of the chassis member in cooperation with the side wall portion.

2. The fan unit according to claim 1, wherein the wiring board is sandwiched between the fixing portion and the bottom portion of the chassis member, and the fixing portion of the bracket member is fixed by screws jointly with the wiring board.

3. The fan unit according to claim 1 or 2, wherein the wiring board includes a plurality of connectors arranged between the fans adjacent to each other and electrically connected to each of the plurality of fans via a cable.

4. The fan unit according to claim 1, wherein engaging means are arranged in both the bracket member and the side wall portion of the chassis member to be engaged with each other.

5. An electronic device comprising:
the fan unit according to claim 1; and
electronic components cooled by the fan unit.

6. A method for manufacturing a fan unit, comprising:
a fan engaging step of engaging surfaces of a plurality of fans arrayed in a direction intersecting an air blowing direction and orthogonal to the air blowing direction with a side wall portion of a chassis member;
a board disposing step of disposing a wiring board to which the plurality of fans is electrically connected in a bottom portion of the chassis member supporting the plurality of fans; and
a bracket fixing step of sandwiching the plurality of fans engaged with the side wall portion of the chassis member between the side wall portion and a bracket member, and fixing the fixing portion of the bracket member to the bottom portion of the chassis member by screws.

7. The method for manufacturing the fan unit according to claim 6, wherein in the bracket fixing step, the wiring board is sandwiched between the fixing portion of the bracket member and the bottom portion of the chassis member, and the fixing portion of the bracket member is fixed to the bottom portion of the chassis member by screws jointly with the wiring board.

8. The method for manufacturing the fan unit according to claim 6 or 7, further comprising a bracket engaging step of engaging the bracket member and the side wall portion of the chassis member with each other via engaging means.
